(19) United States
(12) Patent Application Publication
(10) Pub. No.: US 2015/0053458 A1
(43) Pub. Date: Feb. 26, 2015

(54) INSULATING FILM FOR PRINTED CIRCUIT BOARD AND PRODUCTS HAVING THE SAME

(71) Applicant: SAMSUNG ELECTRO-MECHANICS CO., LTD., Suwon-Si (KR)

(72) Inventors: Choon Keun Lee, Suwon-Si (KR); Dong Hoon Kim, Suwon-Si (KR); Jong Yoon Jang, Suwon-Si (KR); Jae Hyun Jung, Suwon-Si (KR); Jae Choon Cho, Suwon-Si (KR)

(73) Assignee: SAMSUNG ELECTRO-MECHANICS CO., LTD., Suwon-Si (KR)

(21) Appl. No.: 14/309,331

(22) Filed: Jun. 19, 2014

(30) Foreign Application Priority Data
Aug. 26, 2013 (KR) 10-2013-0101247

(51) Int. Cl. H05K 1/03; H05K 1/02

(52) U.S. Cl. CPC H05K 1/036; H05K 1/02; H05K 1/0366; H05K 1/0373
USPC 174/251; 428/414; 428/335

(57) ABSTRACT

Disclosed herein are an insulating film for a printed circuit board and products having the same. In detail, in the insulating film according to a representative embodiment of the present invention, an insulating material in which a content of an inorganic filler in an insulating layer has a concentration gradient and a printed circuit board using the same may increase fillability of an inner layer circuit and a through hole of the inner layer circuit.

### CROSS REFERENCE TO RELATED APPLICATION

This application claims the benefit of Korean Patent Application No. 10-2013-0101247, filed on Aug. 26, 2013, entitled “Insulating Film For Printed Circuit Board And Products Having The Same”, which is hereby incorporated by reference in its entirety into this application.

### BACKGROUND OF THE INVENTION

1. Technical Field The present invention relates to an insulating film for a printed circuit board and products having the same.

2. Description of the Related Art

Recently, with the explosive development of electronic industries, a demand for high-performance, multi-functional, and composite electronic products has increased. With the trend of the electronic products, a demand for high-performance, multi-functional, and composite components has increased. In particular, a demand for multi-functional, fine, and thin printed circuit board among the components has increased. In order to make circuits of the printed circuit board fine and thin, an interest in a film type insulating material having low illumination and a coefficient of thermal expansion, in particular, a polymer composite material has increased. In order to lower a thermal expansion rate of the film type insulating material, there is a need to increase a filling quantity of an inorganic filler. However, there are two problems in a process of the printed circuit board due to the increase in the filling quantity of the inorganic filler.

First, a peel strength between an insulating material and a metal circuit may be reduced. In connection with an adhesion of a build-up insulating film, a physical anchor and a partially chemical anchor between the insulating material and the metal circuit are made by chemically etching a surface of the hardened insulating film to form surface roughness and then performing plating thereon. In this case, the surface roughness and the chemical anchor are limited in the insulating film having the increased filling quantity of the inorganic filler.

Second, at the time of bonding the insulating film, flowability is reduced due to a high viscosity property to limit circuit fillability of the insulating material on an inner layer circuit substrate, such that voids and defects occur in an insulating layer, thereby causing a problem of reliability of the printed circuit board later.

Meanwhile, Patent Document 1 discloses a printed circuit board having an embedded pattern, but has a limitation to fill the insulating film in an inner layer circuit and fill the inner layer circuit in a via hole or a through hole which is formed in the inner layer circuit.

Patent Document 1: Korean Patent No. 1022903

### SUMMARY OF THE INVENTION

In the printed circuit board according to a preferred embodiment of the present invention, it is found that the insulating material in which the content of the inorganic filler of the insulating layer has a concentration gradient and the printed circuit board using the same increase the fillability of the inner layer circuit and the through hole of the inner layer circuit, and the present invention is completed based thereon.

The present invention has been made in an effort to provide an insulating film for a printed circuit board capable of increasing fillability of an inner layer circuit and a through hole of the inner layer circuit.

Further, the present invention has been made in an effort to provide a printed circuit board in which a resin-rich region layer of the insulating layer is stacked on a substrate formed with predetermined circuit patterns by contacting the substrate.

In addition, the present invention has been made in an effort to provide a printed circuit board in which a resin-rich region layer of a prepreg is stacked on a substrate formed with predetermined circuit patterns by contacting the substrate.

According to a preferred embodiment of the present invention, there is provided an insulating film for a printed circuit board, including: a carrier film; an insulating layer formed on the carrier film and including an inorganic filler; and a cover film formed on the insulating layer, wherein a content of the inorganic filler in the insulating layer has a concentration gradient which is reduced in a direction of the cover film from the carrier film.

The insulating layer may be configured of an inorganic filler-rich region layer and a resin-rich region layer and a thickness ratio of the resin-rich region layer to the inorganic filler-rich region layer may be 1:0.25 to 1.5.

A thickness of the insulating layer may be 10 to 40 μm.

The content of the inorganic filler in the inorganic filler-rich region layer may be 70 to 95 wt % with respect to a resin composition and the content of the inorganic filler in the resin-rich region layer may be 20 to 40 wt % with respect to the resin composition.

The carrier film may be made of polyethylene terephthalate (PET) or polyimide (PI), the cover film may be made of polypropylene (PP) or polyethylene (PE), and the insulating layer may be made of a resin composition including an epoxy resin, a hardener, and an inorganic filler.

As the inorganic filler, at least one selected from silica (SiO₂), alumina (Al₂O₃), silicon carbide (SiC), barium sulfate (BaSO₄), talc, mica powder, aluminum hydroxide (AlOH₃), magnesium hydroxide (Mg (OH)₂), calcium carbonate (CaCO₃) , magnesium carbonate (MgCO₃), magnesium oxide (MgO), boron nitride (BN), aluminum borate (AlBO₃), barium titanate (BaTiO₃), and zirconate calcium (CaZrO₃) may be used.

The insulating film may further include a primer layer which is disposed between the carrier film and the insulating layer.

The primer layer may be made of a resin composition including an epoxy resin, a hardener, a hardening accelerator, a thermoplastic resin, and an inorganic filler.

The insulating layer may include a prepreg including a glass fiber.

As the glass fiber, at least one selected from a group consisting of E-glass, T-glass, S-glass, and quarts-glass may be used.

The insulating film may further include a primer layer which is disposed between the carrier film and the prepreg.

The primer layer may be made of a resin composition including an epoxy resin, a to hardener, a hardening accelerator, a thermoplastic resin, and an inorganic filler.

According to another preferred embodiment of the present invention, there is provided a printed circuit board stacked by contacting a surface from which the cover film of the insulating layer as described above is removed to a substrate formed with predetermined circuit patterns.

According to still another preferred embodiment of the present invention, there is provided a printed circuit board stacked by contacting a surface from which the cover film of the prepreg as described above is removed to a substrate formed with predetermined circuit patterns.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of an insulating film according to a preferred embodiment of the present invention;

FIG. 2 is a cross-sectional view of an insulating film further including a primer layer which is disposed between a carrier film and an insulating layer, in an insulating film according to another preferred embodiment of the present invention;

FIG. 3 is a cross-sectional view of an insulating film in which a prepreg including a glass fiber is formed in an insulating layer according to still another preferred embodiment of the present invention;

FIG. 4 is a cross-sectional view of an insulating film further including a primer layer which is disposed between a carrier film and a prepreg, in an insulating film including a prepreg according to another preferred embodiment of the present invention; and

FIGS. 5A to 5E are diagrams schematically illustrating a process of stacking an insulating film according to the representative embodiment of the present invention on a to substrate.

### DESCRIPTION OF THE PREFERRED EMBODIMENTS

Before the present invention is described in more detail, it must be noted that the terms and words used in the present specification and claims should not be interpreted as being limited to typical meanings or dictionary definitions, but should be interpreted as having meanings and concepts relevant to the technical scope of the present invention based on the rule according to which an inventor can appropriately define a concept implied by a term to best describe the method he or she knows for carrying out the invention. Further, the embodiments of the present invention are merely illustrative, and are not to be construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related to the present invention may make the gist of the present invention unclear, a detailed description thereof will be omitted.

Insulating Film

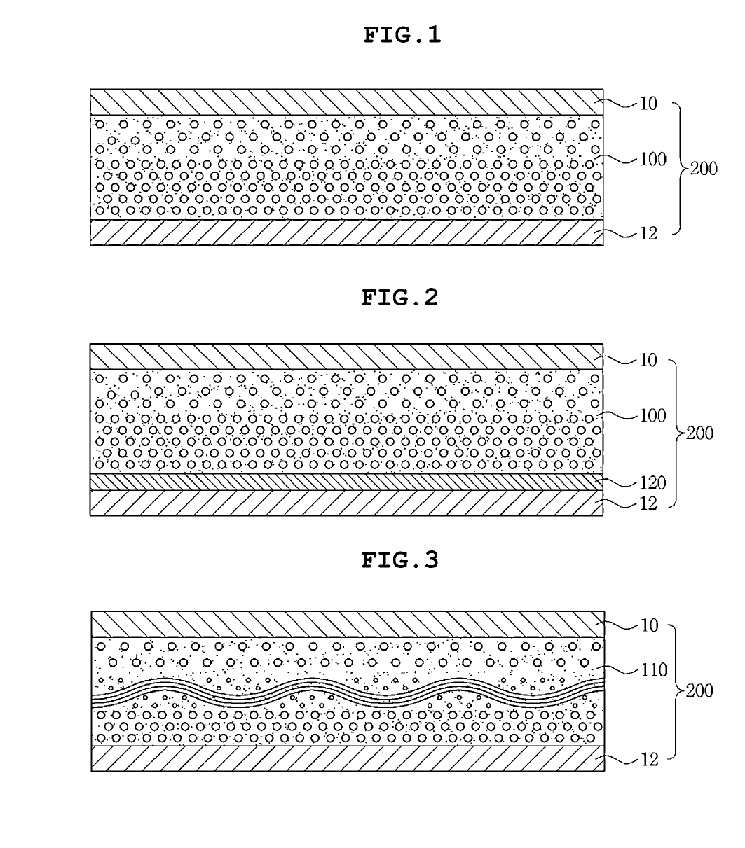

FIG. 1 is a cross-sectional view of an insulating film according to a preferred embodiment of the present invention.

Referring to FIG. 1, an insulating film 200 may be formed by forming an insulating layer 100 including an inorganic filler on a carrier film 12 and stacking a cover film 10 on the insulating layer 100. The carrier film 12 may be made of polyethylene terephthalate (PET), polyimide (PI), or the like, but a material of the carrier film 12 is not limited thereto. In this case, the insulating film 200 is stacked on the substrate and is subjected to a vacuum laminating process and then the carrier film 12 may be finally removed. The cover film 10 to may be made of polypropylene (PP), polyethylene (PE), or the like and when the insulating film 200 is stacked on the substrate, the cover film 10 may be removed by performing the laminating process on circuit patterns. The insulating layer 100 may be made of a resin composition including an epoxy resin, a hardener, a hardening accelerator, a thermoplastic resin, and an inorganic filler and a content of the inorganic filler in the insulating layer 100 has an upper and lower asymmetrical form.

The epoxy resin is not particularly limited, but at least one of a naphthalene epoxy resin, a bisphenol A type epoxy resin, a bisphenol F type epoxy resin, a novolac epoxy resin, a cresol novolac epoxy resin, a rubber modified epoxy resin, a cyclic aliphatic epoxy resin, a silicon-based epoxy resin, a nitrogen-based epoxy resin, and a phosphoric epoxy resin which are generally used may be selected.

Any hardener including a reaction group reacting to an epoxide ring which is generally included in the epoxy resin may be used and therefore, the hardener is not particularly limited. In detail, an example of the hardener may include an aliphatic/aromatic amine-based hardener, cyclic aliphatic amine and derivatives thereof, an acid anhydride-based hardener, a polyamide amine-based hardener, a polysulfide hardener, a phenolic hardener, a bisphenol A type hardener, a dicyandiamide hardener, and the like, and a combination of one or two hardeners may be used.

An example of a hardening accelerator may include tertiary amines, imidazoles, ureas, and the like and a combination of at least one with the hardener may be used.

An example of the thermoplastic resin may include a polyacetal resin, a polyamide resin, a polyamideimide resin, a polyester resin, a phenoxy resin, and the like, and at least one of the resins may be selected.

As the inorganic filler, silica (SiO₂), alumina (Al₂O₃), silicon carbide (SiC), barium sulfate (BaSO₄), talc, mica powder, aluminum hydroxide (AlOH₃), magnesium hydroxide (Mg (OH)₂), calcium carbonate (CaCO₃) , magnesium carbonate (MgCO₃), magnesium oxide (MgO), boron nitride (BN), aluminum borate (AlBO₃), barium titanate (BaTiO₃), and zirconate calcium (CaZrO₃) may be used alone or a combination of at least two thereof may be used. The inorganic filler is not particularly limited, but the inorganic filler having an average particle diameter of 0.01 to 5 μm is preferable.

The insulating layer of the insulating film is 10 to 40 μm and may be divided into an inorganic filler-rich region layer and a resin-rich region layer. When the thickness of the insulating layer is less than 10 μm, the insulating layer may not sufficiently serve as the insulating material when the insulating layer fills the inner layer circuit and when the thickness of the insulating layer exceeds 40 μm, it is difficult to make the printed circuit board thin A thickness ratio of the resin-rich region layer to the inorganic filler-rich region layer in the insulating layer is 1:0.25 to 1.5. When the thickness ratio of the resin-rich region layer is less than 0.25, the flowability of the insulating layer is degraded to cause the problem at the time of filling the inner layer circuit and when the thickness ratio of the resin-rich region layer exceeds 1.5, a property of a coefficient of thermal expansion of the insulating layer may be reduced.

A content of the inorganic filler in the inorganic filler-rich region layer is appropriately 70 to 95 wt % with respect to the resign composition. When the content of the inorganic filler in the inorganic filler-rich region layer is less than 70 wt %, the coefficient of thermal expansion of the insulating layer may be reduced and when the content of the inorganic filler in the inorganic filler-rich region layer exceeds 95 wt %, a brittle of the insulating layer itself may be increased and a problem may occur at the time of laser drill machining The content of the inorganic filler is appropriately 20 to 40 wt % with respect to the resign composition. When the content of the inorganic filler in the resin-rich region layer is less than 20 wt %, the coefficient of thermal expansion of the insulating layer may be reduced and when the content of the inorganic filler in the resin-rich region layer exceeds 40 wt %, the flowability is degraded, such that the difficulty in filling the inner layer circuit may occur.

In the insulating layer, the resin composition is transferred from a service tank including the resin composition to a slot die head in front of a casting facility and the transferred resin composition is discharged onto a carrier fill roll which is traveled through a discharge part of the slot die head. The slot die head may perform a double discharge to form the inorganic filler-rich region layer and the resin-rich region layer of the insulating layer. The insulating layer is formed with an insulating layer having a predetermined thickness, is subjected to a dry process in a casting drying furnace, and then is adhered to the cover film by an adhesion roll, thereby forming the insulating film according to the preferred embodiment of the present invention.

FIG. 2 is a cross-sectional view of an insulating film further including a primer layer which is disposed between a carrier film and an insulating layer, in an insulating film according to another preferred embodiment of the present invention.

Referring to FIG. 2, the insulating film 200 may be formed by further providing a primer layer 120 between the carrier film 12 and the insulating layer 100. When a metal layer is formed on the inorganic filler-rich region layer of the insulating layer 100 by a plating process, the primer layer 120 is formed on the inorganic filler-rich region layer of the insulating layer 100 to increase an adhesion between the insulating layer 100 and the metal layer and is appropriate to have a thickness less than 5 μm. The primer layer 120 may be made of a resin composition including an epoxy resin, a hardener, a hardening accelerator, a thermoplastic resin, and an inorganic filler to strengthen the adhesion with the metal layer. Further, the primer layer 120 is not particularly limited, but may further include a material improving a plating adhesion.

FIG. 3 is a cross-sectional view of an insulating film in which a prepreg including a glass fiber is formed in an insulating layer according to still another preferred embodiment of the present invention.

Referring to FIG. 3, in the insulating film 200, a prepreg 110 including a glass fiber is formed in the insulating layer including the inorganic filler on the carrier film 12. Next, the insulating film may be formed by stacking the cover film 10 on the prepreg 110. The to carrier film may be made of polyethylene terephthalate (PET), polyimide (PI), or the like, but a material of the carrier film 12 is not limited thereto. In this case, the prepreg is stacked on the substrate, a vacuum laminating process is performed, and then the carrier film may be finally removed. The cover film may be made of polypropylene (PP), polyethylene (PE), or the like and when the insulating film including the prepreg is stacked on the substrate, the cover film may be removed by performing the laminating process on the circuit patterns. The prepreg 110 may be made of the resin composition including the epoxy resin, the hardener, the hardening accelerator, the thermoplastic resin, and the inorganic filler and the content of the inorganic filler has the upper and lower asymmetrical form based on the glass fiber included in the prepreg 110.

The glass fiber may be included to improve the property of the coefficient of thermal expansion and is not particularly limited, but at least one selected from a group consisting of E-glass, T-glass, S-glass, and quartz-glass may be used.

The epoxy resin is not particularly limited, but at least one of a naphthalene epoxy resin, a bisphenol A type epoxy resin, a bisphenol F type epoxy resin, a novolac epoxy resin, a cresol novolac epoxy resin, a rubber modified epoxy resin, a cyclic aliphatic epoxy resin, a silicon-based epoxy resin, a nitrogen-based epoxy resin, and a phosphoric epoxy resin which are generally used may be selected.

Any hardener including a reaction group reacting to an epoxide ring which is generally included in the epoxy resin may be used and therefore, the hardener is not particularly limited. In detail, an example of the hardener may include an aliphatic/aromatic amine-based hardener, cyclic aliphatic amine and derivatives thereof, an acid anhydride-based hardener, a polyamide amine-based hardener, a polysulfide hardener, a phenolic hardener, a bisphenol A type hardener, a dicyandiamide hardener, and the like, and a combination of one or two hardeners may be used.

An example of a hardening accelerator may include tertiary amines, imidazoles, ureas, and the like and a combination of at least one with the hardener may be used. An example of the thermoplastic resin may include a polyacetal resin, a polyamide resin, a polyamideimide resin, a polyester resin, a phenoxy resin, and the like, and at least one of the resins may be selected.

As the inorganic filler, silica (SiO2), alumina (Al₂O₃), silicon carbide (SiC), barium sulfate (BaSO₄), talc, mica powder, aluminum hydroxide (AlOH₃), magnesium hydroxide (Mg (OH)₂), calcium carbonate (CaCO₃) , magnesium carbonate (MgCO₃), magnesium oxide (MgO), boron nitride (BN), aluminum borate (AlBO₃), barium titanate (BaTiO₃), and zirconate calcium (CaZrO₃) may be used alone or a combination of at least two thereof may be used. The inorganic filler is not particularly limited, but the inorganic filler having an average particle diameter of 0.01 to 5 μm is preferable.

The prepreg is transferred from a service tank including the resin composition to a slot die head in front of a casting facility and the transferred resin composition is discharged onto a carrier fill roll which is traveled through a discharge part of the slot die head. The slot die head may perform a triple discharge to form the inorganic filler-rich region layer, the resin-rich region layer, and the prepreg including the glass fiber disposed between the inorganic filler-rich region layer and the resin-rich resign layer. The triple discharge sequentially forms the inorganic filler-rich region layer, the glass fiber, and the resin-rich region layer on the carrier film roll and the prepreg is formed with the coating layer having a predetermined thickness, is subjected to the drying process by the casting drying furnace, and is adhered to the cover film by the adhered roll, thereby forming the insulating film according to the preferred embodiment of the present invention.

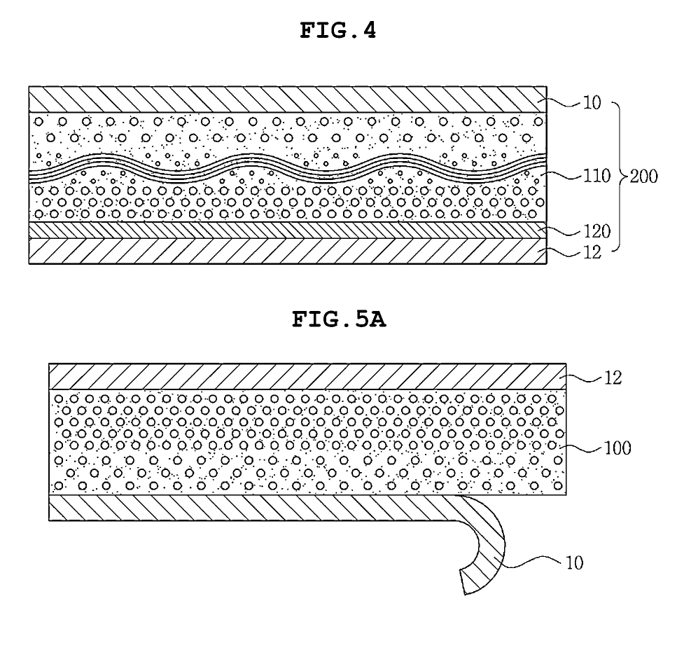

FIG. 4 is a cross-sectional view of an insulating film further including a primer layer which is disposed between a carrier film and a prepreg, in an insulating film including a prepreg according to another preferred embodiment of the present invention.

Referring to FIG. 4, the insulating film 200 may be formed by further providing the primer layer 120 between the carrier film 12 and the prepreg 110. When the metal layer is formed on the inorganic filler-rich region layer of the prepreg by the plating process, the primer layer 120 is formed on the inorganic filler-rich region layer of the prepreg to increase the adhesion between the prepreg and the metal layer and is appropriate to have a thickness less than 5 μm. The primer layer 120 may be made of a resin composition including an epoxy resin, a hardener, a hardening accelerator, a thermoplastic resin, and an inorganic filler to strengthen the adhesion with the metal layer. Further, the primer layer 120 is not particularly limited, but may further include a material improving the plating adhesion.

Printed Circuit Board

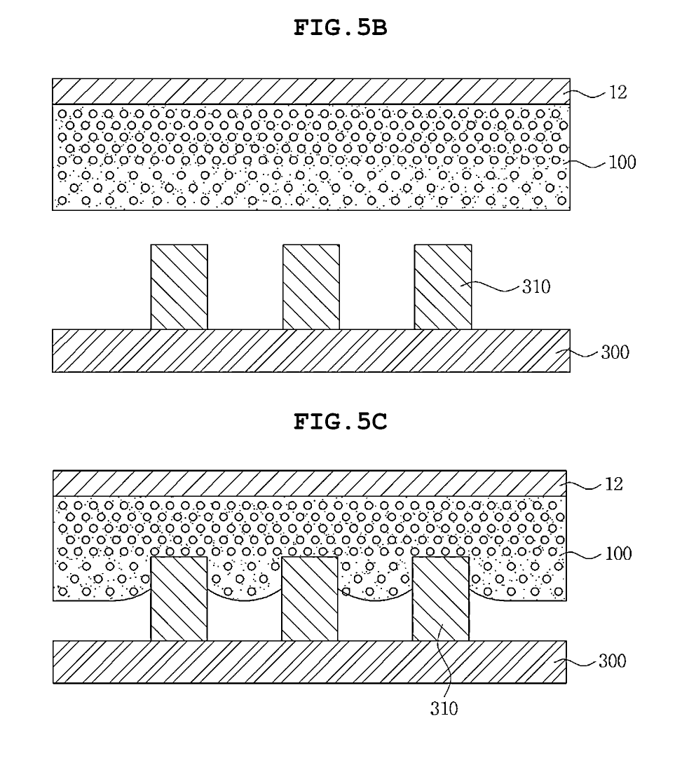

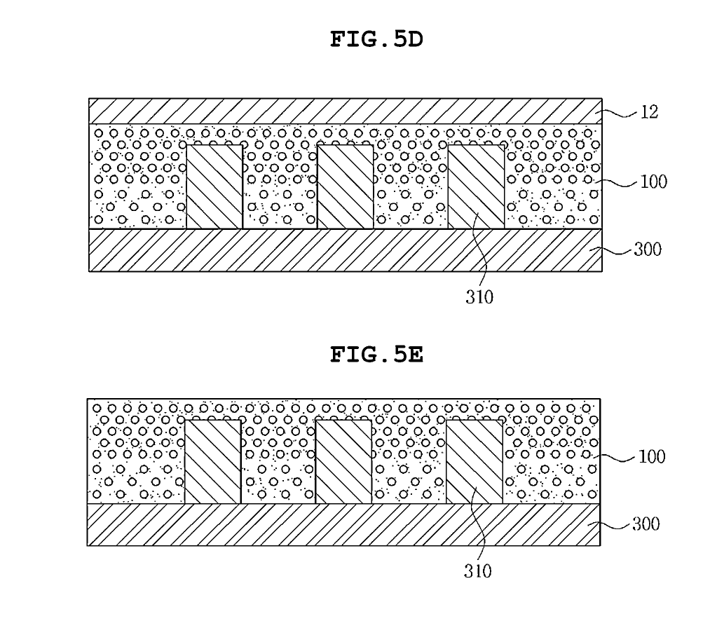

FIGS. 5A to 5E are diagrams schematically illustrating a process of stacking an insulating film according to the representative embodiment of the present invention on a substrate.

Referring to FIGS. 5A and 5B, the insulating film from which the cover film 10 is removed is stacked on a substrate 300 formed with predetermined circuit patterns 310. In this case, a surface stacked on the circuit pattern 310 is a surface of the insulating layer 100 from which the cover film 10 is removed. The reason why the surface of the insulating layer 100 from which the cover film 10 is removed is stacked on the circuit patterns 310 by contacting the circuit patterns 310 is that the resin-rich region layer of the insulating layer 100 has a viscosity lower than that of the inorganic filler-rich region layer and has the flowability than that thereof. As a result, the occurrence of voids between the circuit patterns 310 may be suppressed and the fillability between the circuit patterns 310 may be increased. Further, in the case of filling the via hole or the through hole of the inner layer circuit, the inner layer circuit may be filled without performing a separate plugging process. The insulating film 200 from which the cover film 10 stacked on the substrate 300 is removed is subjected to a hot pressing process, such as the vacuum laminating, and then the carrier film 12 may be finally removed.

Further, although not particularly limited, in addition to the insulating film according to the representative embodiment of the present invention, the insulating film further including the primer layer which is disposed in the insulating layer, the insulating to film including the prepreg, and the insulating film further including the primer layer which is disposed in the prepreg may also be stacked on the substrate formed with the predetermined circuit patterns.

According to the insulating film for the printed circuit board and the products having the same according to the representative embodiment of the present invention, the insulating material in which the content of the inorganic filler in the insulating layer has the concentration gradient and the printed circuit board using the same may increase the fillability of the inner layer circuit and the through hole of the inner layer circuit.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An insulating film for a printed circuit board, comprising:
a carrier film;
an insulating layer formed on the carrier film and including an inorganic filler; and
a cover film formed on the insulating layer,
wherein a content of the inorganic filler in the insulating layer has a concentration gradient which is reduced in a direction of the cover film from the carrier film.

2. The insulating film for a printed circuit board as set forth in claim 1, wherein the insulating layer is configured of an inorganic filler-rich region layer and a resin-rich region layer and a thickness ratio of the resin-rich region layer to the inorganic filler-rich region layer is 1:0.25 to 1.5.

3. The insulating film for a printed circuit board as set forth in claim 2, wherein a thickness of the insulating layer is 10 to 40 μm.

4. The insulating film for a printed circuit board as set forth in claim 2, wherein the content of the inorganic filler in the inorganic filler-rich region layer is 70 to 95 wt % with respect to a resin composition and the content of the inorganic filler in the resin-rich region layer is 20 to 40 wt % with respect to the resin composition.

5. The insulating film for a printed circuit board as set forth in claim 1, wherein the carrier film is made of polyethylene terephthalate (PET) or polyimide (PI), the cover film is made of polypropylene (PP) or polyethylene (PE), and the insulating layer is made of a resin composition including an epoxy resin, a hardener, and an inorganic filler.

6. The insulating film for a printed circuit board as set forth in claim 1, wherein as the inorganic filler, at least one selected from silica (SiO₂), alumina (Al₂O₃), silicon carbide (SiC), barium sulfate (BaSO₄), talc, mica powder, aluminum hydroxide (AlOH₃), magnesium hydroxide (Mg (OH)₂), calcium carbonate (CaCO₃) , magnesium carbonate (MgCO₃), magnesium oxide (MgO), boron nitride (BN), aluminum borate (AlBO₃), barium titanate (BaTiO₃), and zirconate calcium (CaZrO₃) is used.

7. The insulating film for a printed circuit board as set forth in claim 1, wherein the insulating film further includes a primer layer which is disposed between the carrier film and the insulating layer.

8. The insulating film for a printed circuit board as set forth in claim 7, wherein the primer layer is made of a resin composition including an epoxy resin, a hardener, a hardening accelerator, a thermoplastic resin, and an inorganic filler.

9. The insulating film for a printed circuit board as set forth in claim 1, wherein the insulating layer includes a prepreg including a glass fiber.

10. The insulating film for a printed circuit board as set forth in claim 9, wherein as the glass fiber, at least one selected from a group consisting of E-glass, T-glass, S-glass, and quarts-glass is used.

11. The insulating film for a printed circuit board as set forth in claim 9, wherein the insulating film further includes a primer layer which is disposed between the carrier film and the prepreg.

12. The insulating film for a printed circuit board as set forth in claim 11, wherein the primer layer is made of a resin composition including an epoxy resin, a hardener, a hardening accelerator, a thermoplastic resin, and an inorganic filler.

13. A printed circuit board stacked by contacting a surface from which the cover film of the insulating layer as set forth in claim 1 is removed to a substrate formed with predetermined circuit patterns.

14. A printed circuit board stacked by contacting a surface from which the cover film of the prepreg as set forth in claim 9 is removed to a substrate formed with predetermined circuit patterns.
